(19) United States
(12) Patent Application Publication
(10) Pub. No.: US 2020/0021273 A1
(43) Pub. Date: Jan. 16, 2020

(54) FILTER WITH VOLUME ACOUSTIC RESONATORS

(71) Applicant: SAMSUNG ELECTRO-MECHANICS CO., LTD., Suwon-si (KR)

(72) Inventors: Jung Woo SUNG, Suwon-si (KR); June Kyoo LEE, Suwon-si (KR)

(73) Assignee: SAMSUNG ELECTRO-MECHANICS CO., LTD., Suwon-si (KR)

(21) Appl. No.: 16/281,523

(22) Filed: Feb. 21, 2019

(30) Foreign Application Priority Data
Jul. 10, 2018 (KR) 10-2018-0080215

(51) Int. Cl. H03H 9/54; H03H 9/02

(52) U.S. Cl. CPC H03H 9/542; H03H 9/02007

(57) ABSTRACT

A filter includes a series unit including a plurality of series resonators, and a shunt unit including a plurality of shunt resonators, wherein each of the plurality of shunt resonators is disposed between the plurality of series resonators and a ground. Each of the plurality of series resonators and the plurality of shunt resonators comprises a volume acoustic resonator, and a resonance frequency of a portion of shunt resonators among the plurality of shunt resonators may be equal to a resonance frequency of the plurality of series resonators.

### CROSS-REFERENCE TO RELATED APPLICATION

This application claims the benefit under 35 USC 119(a) of Korean Patent Application No. 10-2018-0080215 filed on Jul. 10, 2018 in the Korean Intellectual Property Office, the entire disclosure of which is incorporated herein by reference for all purposes.

### BACKGROUND

### 1. Field

The present disclosure relates to a filter with volume acoustic resonators.

### 2. Description of Related Art

With the rapid development of mobile communication devices, chemical and biological testing devices, and similar devices, the demand for small and light filters, oscillators, resonant elements, acoustic resonant mass sensors, and similar components, used in such devices, has also increased.

A film bulk acoustic resonator (FBAR) is typically used to implement such small and light filters, oscillators, resonant elements, acoustic resonant mass sensors, and similar components. The film bulk acoustic resonator (FBAR) may be mass produced at minimal cost, and may be implemented to have subminiature sizes. In addition, the FBAR may have a high-quality factor (Q) value, a main characteristic of a filter, may be used even in a microwave frequency band, and may particularly implement bands of a personal communications system (PCS) and a digital cordless system (DCS).

Generally, the FBAR has a structure including a resonating unit which is implemented by sequentially laminating a first electrode, a piezoelectric layer, and a second electrode on a substrate. An operating principle of the FBAR will be described below. First, an electric field is induced in a piezoelectric layer by an electric energy applied to first and second electrodes, and then a piezoelectric phenomenon may occur in the piezoelectric layer by the induced electric field, thereby causing the resonating unit to vibrate in a predetermined direction. As a result, a bulk acoustic wave may be generated in the same direction as the direction in which the resonating unit is vibrating, thereby generating resonance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a filter includes a series unit including a plurality of series resonators; and a shunt unit including a plurality of shunt resonators, wherein the plurality of shunt resonators is disposed between the plurality of series resonators and a ground; and wherein each of the plurality of series resonators and each of the plurality of shunt resonators includes a volume acoustic resonator, and a resonance frequency of a first set of shunt resonators among the plurality of shunt resonators is equal to a resonance frequency of the plurality of series resonators.

The resonance frequency of the first set of shunt resonators among the plurality of shunt resonators may be different from a resonance frequency of a second set of shunt resonators of the plurality of shunt resonators.

Each of the plurality of series resonators may be configured to have a same resonance frequency.

Each of a second set of shunt resonators among the plurality of shunt resonators may have a same resonance frequency.

The series unit may include the plurality of series resonators.

The shunt unit may include a trimming inductor connected to each of the first set of shunt resonators.

The trimming inductor may improve at least one of an insertion loss and a reflection loss of the filter.

The filter may have a bandwidth of 100 to 200 MHz.

In a general aspect, a filter includes a series unit including a plurality of series resonators, and a shunt unit including a plurality of shunt resonators, wherein the plurality of shunt resonators is disposed between the plurality of series resonators and a ground, and wherein a first set of series resonators of the plurality of series resonators, and a first set of shunt resonators of the plurality of shunt resonators have a different resonance frequency; and the resonance frequency of a second set of shunt resonators among the plurality of shunt resonators is equal to the resonance frequencies of the plurality of series resonators.

The resonance frequency of the first set of shunt resonators among the plurality of shunt resonators may be different from the resonance frequency of the second set of shunt resonators.

Each of the plurality of series resonators may be configured to have a same resonance frequency.

The series unit may include the plurality of series resonators.

The shunt unit may include a trimming inductor connected to each of the first set of shunt resonators.

The trimming inductor may improve at least one of insertion loss and reflection loss of the filter.

The filter may have a bandwidth of 100 to 200 MHz.

Each of the plurality of series resonators and the plurality of shunt resonators may include a volume acoustic resonator.

In another general aspect, a filter includes a series unit including a plurality of series resonators, and a shunt unit including a plurality of shunt resonators, wherein the plurality of shunt resonators is disposed between the plurality of series resonators and a ground, and wherein each of the plurality of series resonators and the plurality of shunt resonators comprises a volume acoustic resonator, and a resonance frequency of a first set of series resonators among the plurality of series resonators is equal to the resonance frequency of the plurality of shunt resonators.

The resonance frequency of the first set of series resonators among the plurality of series resonators may be different from the resonance frequency of a second set of series resonators of the plurality of series resonators.

Each of the plurality of shunt resonators may have a same resonance frequency.

The series unit may include a trimming inductor connected in parallel to each of the first set of series resonators.

The first set of shunt resonators may correspond to one or more than one shunt resonators, and the second set of shunt resonators may correspond to one or more than one shunt resonators.

The first set of series resonators may correspond to one or more than one series resonators, the first set of shunt resonators may correspond to one or more than one shunt resonators, and the second set of shunt resonators may correspond to one or more than one shunt resonators.

The first set of series resonators may correspond to one or more than one series resonators, and the second set of series resonators may correspond to one or more than one series resonators.

Other features and aspects will be apparent from the following detailed description, the drawings, and the claims.

### BRIEF DESCRIPTION OF THE DRAWINGS

FIG. 1 is a cross-sectional view illustrating a filter according to an example;

FIG. 2 is an example of a block diagram of a filter;

FIG. 3 illustrates an example of a circuit diagram of a filter;

FIG. 4 illustrates an example of a frequency response of the filter of FIG. 3;

FIG. 5 is a circuit diagram of a filter according to an example;

FIG. 6 is a simulation graph of a filter according to an example;

FIG. 7 is an example of a simulation graph of a comparative example; and

FIG. 8 is a circuit diagram of a filter according to another example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

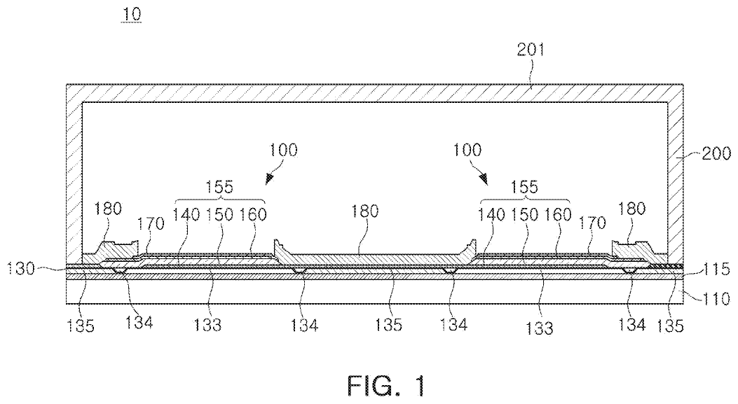

FIG. 1 is a cross-sectional view illustrating a filter according to an example.

Referring to FIG. 1, a filter 10 according to an example may include at least one volume acoustic resonator 100 and a cap 200. In FIG. 1, the filter 10 is illustrated as including two volume acoustic resonators 100, but this is only an example. The filter 10 may include one volume acoustic resonator 100, two volume acoustic resonators 100, or three or more volume acoustic resonators 100. The volume acoustic resonator 100 may be a thin film bulk acoustic resonator (FBAR).

The volume acoustic resonator 100 may be constituted by a laminated structure composed of a plurality of films. The laminated structure constituting the volume acoustic resonator 100 may include a substrate 110, an insulating layer 115, an air cavity 133, a support unit 134, an auxiliary support unit 135, and a resonating unit 155 having a first electrode 140, a piezoelectric layer 150, and a second electrode 160, and may further include a protective layer 170 and a metal layer 180.

According to a manufacturing process of the volume acoustic resonator 100 according to an example, a sacrificial layer may be formed on the insulating layer 115, and then a portion of the sacrificial layer may be removed to form a pattern provided with the support unit 134. Here, the auxiliary support unit 135 may be formed by a remaining sacrificial layer. A width of an upper surface of a pattern formed on the sacrificial layer may be wider than a width of a lower surface, and a side surface connecting the upper surface and the lower surface may be inclined. After forming the pattern on the sacrificial layer, a membrane 130 may be formed on the insulating layer 115 exposed externally by the sacrificial layer and the pattern. After forming the membrane 130, an etch stop material (not shown) underlying formation of the support unit 134 may be formed to cover the membrane 130.

After forming the etch stop material, one surface of the etch stop material is planarized such that the membrane 130 formed on the upper surface of the sacrificial layer is exposed externally. In the process of planarizing one surface of the etch stop material, a portion of the etch stop material may be removed, and then the support unit 134 may be formed by an etch stop material remaining in the pattern after the portion of the etch stop material is removed. As a result of the planarization process of the etch stop material, one surface of the support unit 134 and the sacrificial layer may be generally flat. Here, the membrane 130 may function as a stop layer of the planarization process of the etch stop material.

Thereafter, the air cavity 133 may be formed by an etching process in which the sacrificial layer is etched and removed after the first electrode 140, the piezoelectric layer 150, the second electrode 160, and similar layers are laminated. For example, the sacrificial layer may include polycrystalline silicon (Poly-Si). The air cavity 133 may be located at a lower portion of a resonating unit 155 such that the resonating unit 155 composed of the first electrode 140, the piezoelectric layer 150, and the second electrode 160 may vibrate in a predetermined direction.

The substrate 110 may be composed of a silicon substrate, and the insulating layer 115 may be provided on the upper surface of the substrate 110 to electrically isolate the resonating unit 155 from the substrate 110. The insulating layer 115 may be formed of, but not limited to, at least one of silicon dioxide (SiO2), silicon nitride (Si3N4), aluminum oxide (Al2O2), and aluminum nitride (AlN), and may be formed on the substrate 110 by chemical vapor deposition, RF magnetron sputtering (RF Magnetron Sputtering) or evaporation, for example.

An etch stop layer (not shown) may be additionally formed on the insulating layer 115. The etch stop layer serves to protect the substrate 110 and the insulating layer 115 from the etching process, and may serve as a stereobate necessary for depositing other layers on the etch stop layer.

The air cavity 133 and the support unit 135 may be formed on the insulating layer 115. As described above, the air cavity 133 may be formed by an etching process in which a sacrificial layer is etched and removed, after forming a pattern in which the sacrificial layer is formed on the insulating layer 115 and the support unit 134 is provided on the sacrificial layer, and then forming the first electrode 140, the piezoelectric layer 150, the second electrode 160, and laminated.

The air cavity 133 may be located at a lower portion of the resonating unit 155 such that the resonating unit 155, which is composed of the first electrode 140, the piezoelectric layer 150, and the second electrode 160, may vibrate in a predetermined direction. The support unit 134 may be provided on one side of the air cavity 133.

The thickness of the support unit 134 may be the same as the thickness of the air cavity 133. However, this is only an example. The thickness of the support unit 134 and the air cavity may be different from each other. Thus, the upper surfaces provided by the air cavity 133 and the support unit 134 may be substantially flat. According to an example, the resonating unit 155 may be disposed on a planarized surface from which a step is removed, such that an insertion loss and an attenuation characteristic of the volume acoustic resonator may be improved.

A cross-section of the support unit 134 may have a substantially trapezoidal shape, but this is only an example. Specifically, the width of the upper surface of the support unit 134 may be wider than the width of the lower surface, a side surface connecting the upper surface and the lower surface may be inclined. The support unit 134 may be formed of a material which is not etched in an etching process to remove the sacrificial layer. For example, the support unit 134 may be formed of the same material as the insulating layer 115, and specifically, the support unit 134 may be formed of one of silicon dioxide (SiO₂) and silicon nitride (Si₃N₄), or a combination thereof.

According to an example, the side surface of the support unit 134 may be formed to be inclined to prevent an abrupt step from occurring at a boundary between the support unit 134 and the sacrificial layer, and the width of the lower surface of the support unit 134 may be formed to be narrow to prevent an occurrence of a dishing phenomenon. For example, an angle between the lower surface and the side surface of the support unit 134 may be 110° to 160°, and the width of the lower surface of the support unit 134 may be 2 μm to 30 μm.

The auxiliary support unit 135 may be provided outside of, or external to, the support unit 134. The auxiliary support unit 135 may be formed of the same material as the support unit 134, or may be formed a different material from the support unit 134. For example, when the auxiliary support unit 135 is formed of a different material from the material of the support unit 134, the auxiliary support unit 135 may correspond to one portion of the sacrificial layer formed on the insulating layer 115 which remains after the etching process.

A resonating unit 155 may include the first electrode 140, the piezoelectric layer 150 and the second electrode 160. A common area overlapping in a vertical direction of the first electrode 140, the piezoelectric layer 150, and the second electrode 160 may be located at an upper portion of the air cavity 133. The first electrode 140 and the second electrode 160 may be formed of one of gold (Au), titanium (Ti), tantalum (Ta), molybdenum (Mo), ruthenium (Ru), platinum (Pt), tungsten (W), aluminum (Al), iridium (Ir), and nickel (Ni), or an alloy thereof. The piezoelectric layer 150 is a layer causing a piezoelectric effect converting electrical energy into mechanical energy in the form of elastic waves. In the piezoelectric layer 150, zinc oxide (ZnO), aluminum nitride (AlN), doped aluminum nitride, lead zirconate titanate, quartz, and the like may be selectively used. In the case of the doped aluminum nitride, it may further include a rare earth metal transition metal, or an alkaline earth metal. For example, it may include a rare earth metal transition metal and an alkaline earth metal. For example, the rare earth metal may include at least one of scandium (Sc), erbium (Er), yttrium (Y), and lanthanum (La), and a rare earth content may include 1 to 20 at %. The transition metal may include at least one of hafnium (Hf), titanium (Ti), zirconium (Zr), tantalum (Ta), and niobium (Nb). In addition, the alkaline earth metal may also include magnesium (Mg).

A membrane 130 is formed of a material which may not be easily removed in the process of forming the air cavity 133. For example, when a halide-based etching gas such as fluorine (F), chlorine (Cl), or similar gas is used to remove a portion of the sacrificial layer to form the cavity 133, the membrane 130 may be formed of a material having a low reactivity with the etching gas. In this example, the membrane 130 may include at least one of silicon dioxide (SiO2) and silicon nitride (Si3N4). In addition, the membrane 130 may be formed of a dielectric layer containing at least one material of magnesium oxide (MgO), zirconium oxide (ZrO2), aluminum nitride (AlN), lead zirconate titanate (PZT), gallium arsenide (GaAs), hafnium oxide (HfO2), aluminum oxide (Al2O3), titanium oxide (TiO2), and zinc oxide (ZnO), or may be formed of a metal layer containing at least one material of aluminum (Al), nickel (Ni), chrome (Cr), platinum (Pt), gallium (Ga), and hafnium (Hf).

According to various examples, a seed layer made of the aluminum nitride (AlN) may be formed on the membrane 130. Specifically, the seed layer may be disposed between the membrane 130 and the first electrode 140. The seed layer may be formed using a dielectric or metal having an HCP structure in addition to aluminum nitride (AlN). In the example where a metal, for example, the seed layer may be formed of titanium (Ti).

The protective layer 170 may be disposed on the second electrode 160 to prevent the second electrode 160 from being exposed to external influences. The protective layer 170 may be formed of one insulating material of a silicon oxide series, a silicon nitride series and an aluminum nitride series, and an aluminum oxide series, but is not limited thereto. A metal layer 180 may be formed on the first electrode 140 and the second electrode 160, which have portions that are exposed externally.

The resonating unit 155 may be divided into an active area and an inactive area. The active area of the resonating unit 155 is an area which vibrates and resonates in a predetermined direction by a piezoelectric phenomenon generated in the piezoelectric layer 150 when an electric energy such as a radio frequency signal is applied to the first electrode 140 and the second electrode 160, and corresponds to an area in which the first electrode 140, the piezoelectric layer 150, and the second electrode 160 are superimposed in a vertical direction at an upper portion of the air cavity 133. The inactive area of the resonating unit 155 is an area which is not resonated by the piezoelectric phenomenon even when the electric energy is applied to the first electrode 140 and the second electrode 160, and corresponds to an area that is exterior to the active area.

The resonating unit 155 outputs a radio frequency signal having a specific frequency by using the piezoelectric phenomenon. Specifically, the resonating unit 155 may output the radio frequency signal having a resonance frequency corresponding to vibration according to the piezoelectric phenomenon of the piezoelectric layer 150.

A cap 200 may be bonded to a laminated structure forming one or more volume acoustic resonators 100. The cap 200 may be formed in a cover shape having an internal space in which one or more volume acoustic resonators 100 are accommodated. The cap 200 may be formed in a hexahedron shape having a lower surface opened, and may include an upper portion and a plurality of side portions connected to the upper portion. However, the shape of the cap 200 is not limited thereto.

The cap 200 may be formed with an accommodating unit in a center to accommodate the resonating unit 155 including the one or more volume acoustic resonators 100. The laminated structure may be bonded to a plurality of side portions in a bonding area, and the bonding area of the laminated structure may correspond to an edge of the laminated structure. The cap 200 may be bonded to the substrate 110, which is laminated on the substrate 110. In another example, the cap 200 may be bonded to at least one of the protective layer 170, the membrane 130, and the insulating layer 115, the first electrode 140, the piezoelectric layer 150, the second electrode 160, and the metal layer 180.

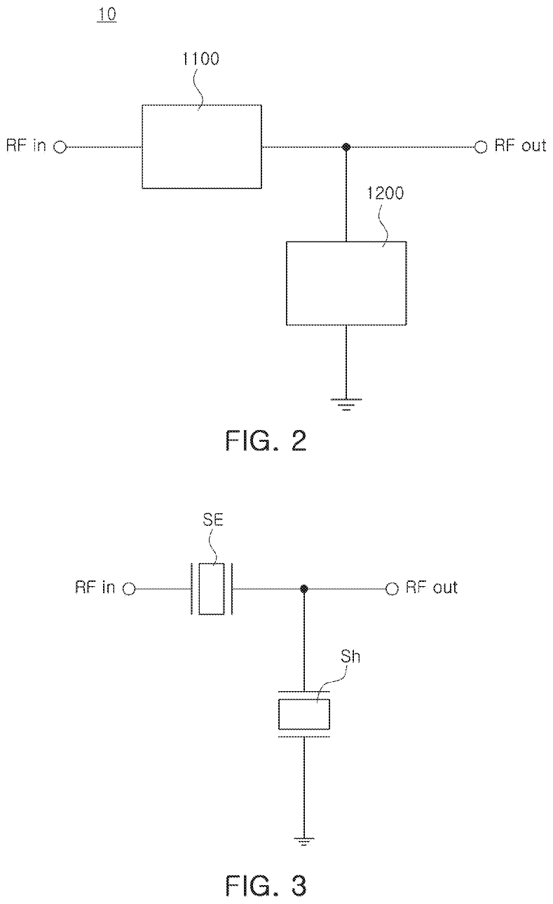

FIG. 2 is an example block diagram of a filter.

Referring to FIG. 2, the filter 10 may include at least one series unit 1100 and at least one shunt unit 1200 disposed between the at least one series unit 1100 and a ground. The filter 10, as illustrated in FIG. 2, may be formed of a filter structure of a ladder type, or conversely, may be formed of a filter structure of a lattice type.

At least one series unit 1100 may be connected between a signal input terminal (RFin) inputting an input signal and a signal output terminal (RFout) outputting an output signal, and the shunt unit 1200 may be connected between the series unit 1100 and a ground. According to FIG. 2, the filter 10 is illustrated to include one series unit 1100 and a shunt unit 1200. However, a plurality of series units 1100 and shunt units 1200 may be provided. When the plurality of series units 1100 and shunt units 1200 are provided, the plurality of series units 1100 may be connected in series, and the shunt units 1200 may be disposed or connected between some of the nodes between the serially connected series units 100 and a ground.

Each of at least one series unit 1100 and at least one shunt unit 1200 may include at least one volume acoustic resonator as illustrated in FIG. 1.

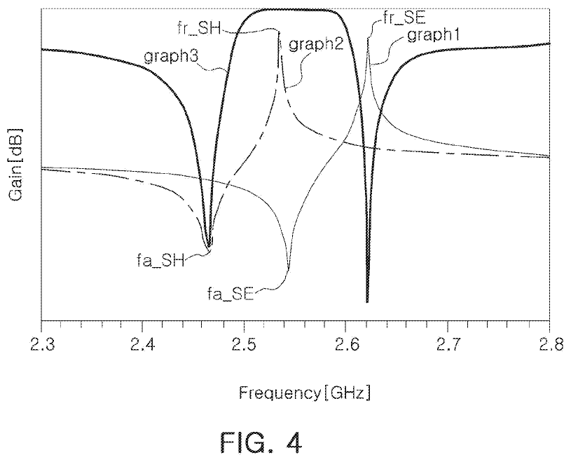

FIG. 3 illustrates an example circuit diagram of a filter, and FIG. 4 illustrates a frequency response of the filter of FIG. 3.

Referring to FIG. 3, the filter may include a series resonator (SE) disposed between a signal input terminal (RFin) and a signal output terminal (RFout), and a shunt resonator (Sh) disposed between the series resonator (SE) and a ground.

Referring to FIG. 4, a first graph (Graph 1) represents a frequency response by the series resonator (SE), a second graph (Graph 2) represents a frequency response by the shunt resonator (Sh), and a third graph (Graph 3) represents a frequency response by a filter including the series resonator (SE) and the shunt resonator (Sh).

The frequency response by the series resonator (SE) has a resonance frequency (fr_SE) and an antiresonance frequency (fa_sh), and the frequency response by the shunt resonator (Sh) has a resonance frequency (fr_Sh) and an antiresonance frequency (fa_Sh).

Referring to the frequency response of the filter, a bandwidth of the filter may be determined by the antiresonance frequency (fa_SH) of the shunt resonator (Sh) and the resonance frequency (fr_SE) of the series resonator (SE).

In order for the filter to be implemented as a bandwidth pass filter, the resonance frequency (fr_SE) of the series resonator (SE) should be higher than the resonance frequency (fr_Sh) of the shunt resonator (Sh), and the antiresonance frequency (fa_SE) of the series resonator (SE) should be higher than the antiresonance frequency (fa_Sh) of the shunt resonator (Sh). For example, the piezoelectric layer of the shunt resonator (Sh) may be designed to be thicker than the piezoelectric layer of the series resonator (SE), such that a relationship between the resonance frequency and the antiresonance frequency, as described above, may be set. On the other hand, a bandwidth and an effective electromechanical coupling coefficient, Kt² may be defined according to the following Equation 1.

$${Kt}^{2} = \frac{{π}^{2}}{4} * \frac{f {a}_{SH} - {fr}_{SH}}{{fr}_{SH}} * 100 \qquad Equation 1$$

On the other hand, the inductor may be connected in parallel with the series resonator (SE), or the inductor may be connected in series with the shunt resonator (SH), such that the bandwidth of the filter may be widely adjusted. When the inductor is connected in parallel with the series resonator (SE), the antiresonance frequency (fa_SE) may be adjusted to be high, such that the bandwidth may be widened. However, when the inductor is connected in parallel with the series resonator (SE), harmonics of the antiresonance frequency may be generated, and an attenuation characteristic may be deteriorated, and an inductor which has a sufficiently high inductance may be implemented to increase the bandwidth, such that the coefficient Q and the insertion loss characteristics may be deteriorated. Additionally, when the inductor is connected in parallel with the series resonator (SE), since a pad for connecting the series resonator (SE) and the inductor should be additionally provided in the filter, an area of the filter may increase.

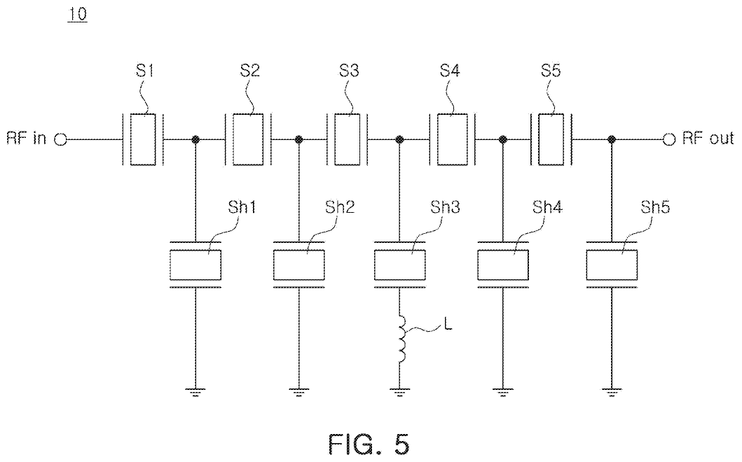

FIG. 5 is a circuit diagram of a filter according to an example.

Referring to FIG. 5, the filter 10 may include a plurality of series resonators (S1 to S5) and a plurality of shunt resonators (Sh1 to Sh5). In the example, the plurality of series resonators (S1 to S5) corresponds to the configuration included in the series unit of FIG. 2, the plurality of shunt resonators may correspond to the configuration included in the shunt unit of FIG. 2, and each of the plurality of series resonators (S1 to S5) and the plurality of shunt resonators (Sh1 to Sh5) may be configured by the volume acoustic resonator.

The plurality of series resonators (S1 to S5) may be connected in series between the signal input terminal (RFin) and the signal output terminal (RFout). For example, the first series resonator 51, the second series resonator S2, the third series resonator S3, the fourth series resonator S4, and the fifth series resonator S5 may be connected in series. The series unit according to an example may be composed of only the plurality of series resonators (S1 to S5) without any additional elements, unnecessary pads may be removed, and the area of the filter may be efficiently reduced.

The plurality of shunt resonators (Sh1 to Sh5) may individually be disposed or connected between the plurality of series resonators 51 to S5 and a ground. For example, each of the plurality of shunt resonators (Sh1 to Sh5) may be disposed between different series resonators (S1 to S5) and a ground.

The first shunt resonator Sh1 may be disposed between a node between the first series resonator S1 and the second series resonator S2 and a ground, the second shunt resonator Sh2 may be disposed between a node between the second series resonator S2 and the third series resonator S3 and a ground, the third shunt resonator Sh3 may be disposed between a node between the third series resonator S3 and the fourth series resonator S4 and a ground, the fourth shunt resonator Sh4 may be disposed between a node between the fourth series resonator S4 and the fifth series resonator S5 and a ground, and the fifth shunt resonator Sh5 may be disposed between a node between the fifth series resonator S5 and the signal output terminal (RFout) and a ground.

The plurality of series resonators (S1 to S5) and the plurality of shunt resonators (Sh1 to Sh5) provided in the filter 10 according to an example, may have two different resonance frequencies. In other words, a first portion or a first set of resonators of the plurality of series resonators (S1 to S5) and a first portion or a first set of the plurality of shunt resonators (Sh1 to Sh5) may have a first resonance frequency, and a second portion or a second set of series resonators and a second portion or second set of the plurality of shunt resonators (Sh1 to Sh5) may have a second resonance frequency.

In an example, the first set of series resonators may be equal to one series resonator or more than one series resonators. Similarly, the first set of the plurality of shunt resonators may be equal to one or more than one shunt resonators.

Hereinafter, for convenience of description, a design of the filter according to the example will be described focusing on the resonance frequencies of the plurality of series resonators (S1 to S5) and the plurality of shunt resonators (Sh1 to Sh5). However, the following description may be applied to the antiresonance frequencies of the plurality of series resonators (S1 to S5) and the plurality of shunt resonators (Sh1 to Sh5).

The resonance frequency of the volume acoustic resonator may be determined according to the thickness of the film of the laminated structure composed of the plurality of films of FIG. 1. For example, the resonance frequency of the resonator may be determined according to the thickness of the piezoelectric layer.

Therefore, each of the plurality of resonators provided in the filter may have a plurality of resonance frequencies, the thickness of the films of the laminated structures of the respective resonators may be designed to be different from each other. However, when designing the thicknesses of the films of the plurality of resonators to be different from each other, a problem which a process yield is deteriorated accompanied by a plurality of processes occurs.

According to an example, the filter 10 may be composed of resonators having two different resonance frequencies, such that the filter may be easily designed.

However, when the plurality of series resonators (S1 to S5) and the plurality of shunt resonators (Sh1 to Sh5) are designed to have different resonance frequencies, there is a problem which a pass band of the filter 10 is narrow.

The filter 10 according to an example may be configured such that the resonance frequency of some of the shunt resonators among the plurality of shunt resonators (Sh1 to Sh5) is equal to the resonance frequency of the plurality of series resonators (S1 to S5), such that a bandwidth of a broadband may be secured. For example, the filter according to an example may have a bandwidth of 100 to 200 MHz.

Specifically, each of the plurality of series resonators (S1 to S5) may have the same resonance frequencies. The resonance frequency of a first set of shunt resonators among the plurality of shunt resonators (Sh1 to Sh5) may be equal to the resonance frequency of the plurality of series resonators (S1 to S5), and the resonance frequency of a second set of shunt resonators may be different from the resonance frequencies of the plurality of series resonators (S1 to S5). Additionally, each of the resonance frequencies of the second set of shunt resonators may be equal to each other.

For example, the resonance frequency of the third shunt resonator Sh3 may be different from the resonance frequency of the first shunt resonator Sh1, the second shunt resonator Sh2, the fourth shunt resonator Sh4, and the fifth shunt resonator Sh5, and the resonance frequency of the third shunt resonator Sh3 may be the same as the resonance frequency of the plurality of series resonators (S1 to S5). Hereinafter, for convenience of explanation, it will be described assuming that the third shunt resonator Sh3 corresponds to some shunt resonators, such that the resonance frequency of the third shunt resonator Sh3 is different from the resonance frequency of the remaining shunt resonators Sh1, Sh2, Sh4, and Sh5, and is equal to the resonance frequencies of the plurality of series resonators (S1 to S5).

A trimming inductor L may be disposed between the third shunt resonator Sh3 and a ground according to an example. The trimming inductor L may be disposed between the third shunt resonator Sh3 and the ground, such that an insertion loss and a return loss may be improved within a bandwidth.

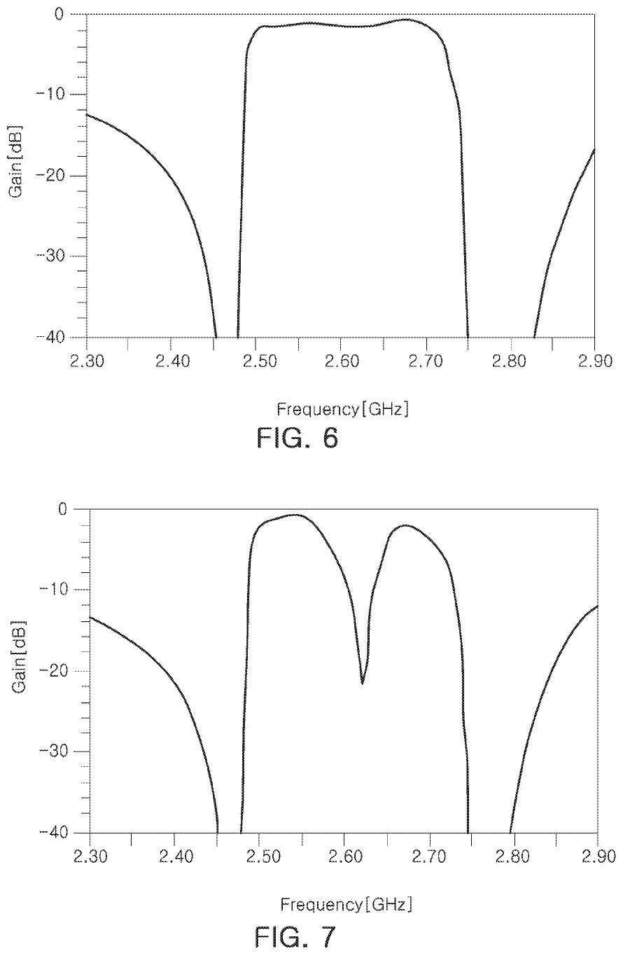

FIG. 6 is a simulation graph of a filter according to an example, and FIG. 7 is a simulation graph of a comparative example corresponding to another example.

FIG. 6 is an example in which the third shunt resonator Sh3 corresponding to a first set of shunt resonators has a resonance frequency of a series resonator, and an FIG. 7 corresponds to an example in which the third resonator Sh3 corresponding to a second set of shunt resonators which have a resonance frequency of a shunt resonator.

Comparing the example of FIG. 6 with the example of FIG. 7, in the case of an example of the present disclosure, the trimming inductor L may be connected to the third shunt resonator Sh3 corresponding to some shunt resonators, such that the insertion loss and the return loss may be improved within a bandwidth of about 2.5 GHz to 2.7 GHz, and the pass characteristic may be improved, as compared to the comparative example.

On the other hand, according to the above-description, the resonance frequency of a portion of shunt resonators among the plurality of shunt resonators (Sh1 to Sh5) may be the same as the resonance frequency of the plurality of series resonators (S1 to S5), and the trimming inductor may be disposed between the portion of shunt resonators and a ground, but according to various examples, the resonance frequency of a portion of series resonators among the plurality of series resonators (S1 to S5) may be equal to the resonance frequency of the plurality of shunt resonators (Sh1 to Sh5), and the trimming inductor may be disposed in parallel with a portion of series resonators.

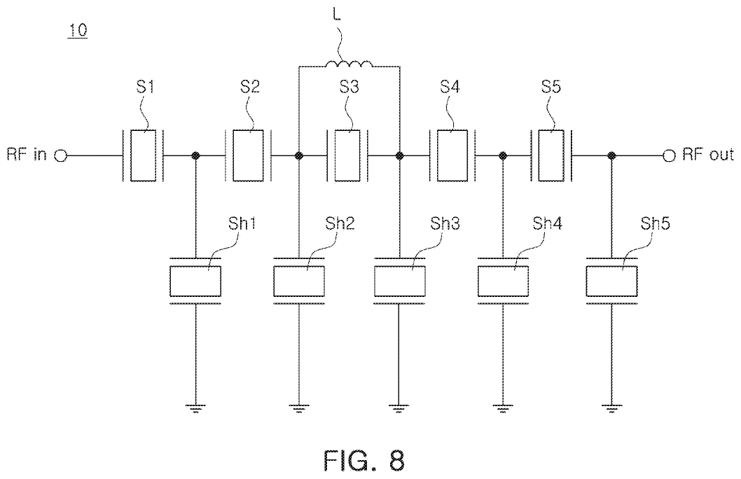

Specifically, referring to FIG. 8, the filter 10 may include a plurality of series resonators (S1 to S5) and a plurality of shunt resonators (Sh1 to Sh5). The resonance frequency of a portion of series resonators among the plurality of series resonators (S1 to S5) may be the same as the resonance frequency of the plurality of shunt resonators (Sh1 to Sh5). Assuming that the third series resonator S3 corresponds to a portion of series resonators, the resonance frequency of the third series resonator S3 may be different from the resonance frequency of the remaining series resonators S1, S2, S4, and S5, and may be the same as the resonance frequency of the plurality of shunt resonators (Sh1 to Sh5). In addition, a trimming inductor L may be disposed in parallel with the third series resonator S3.

As set forth above, according to an example, a series unit may be constituted by only a resonator without any additional elements, and unnecessary pads may be removed, such that an area of a filter may be efficiently removed.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A filter comprising:
a series unit comprising a plurality of series resonators; and
a shunt unit comprising a plurality of shunt resonators;
wherein the plurality of shunt resonators is disposed between the plurality of series resonators and a ground; and
wherein each of the plurality of series resonators and each of the plurality of shunt resonators comprises a volume acoustic resonator, and a resonance frequency of a first set of shunt resonators among the plurality of shunt resonators is equal to a resonance frequency of the plurality of series-connected resonators.

2. The filter of claim 1, wherein the resonance frequency of the first set of shunt resonators among the plurality of shunt resonators is different from a resonance frequency of a second set of shunt resonators of the plurality of shunt resonators.

3. The filter of claim 1, wherein each of the plurality of series resonators is configured to have a same resonance frequency.

4. The filter of claim 1, wherein each of a second set of shunt resonators among the plurality of shunt resonators is configured to have a same resonance frequency.

5. The filter of claim 3, wherein the series unit comprises the plurality of series resonators.

6. The filter of claim 1, wherein the shunt unit comprises a trimming inductor connected to each of the first set of shunt resonators.

7. The filter of claim 6, wherein the trimming inductor improves at least one of an insertion loss and a reflection loss of the filter.

8. The filter of claim 1, wherein the filter has a bandwidth of 100 to 200 MHz.

9. A filter comprising:
a series unit comprising a plurality of series resonators; and
a shunt unit comprising a plurality of shunt resonators;
wherein the plurality of shunt resonators is disposed between the plurality of series resonators and a ground; and
wherein a first set of series resonators of the plurality of series resonators, and a first set of shunt resonators of the plurality of shunt resonators have a different resonance frequency; and
the resonance frequency of a second set of shunt resonators among the plurality of shunt resonators is equal to the resonance frequencies of the plurality of series resonators.

10. The filter of claim 9, wherein the resonance frequency of the first set of shunt resonators among the plurality of shunt resonators is different from the resonance frequency of the second set of shunt resonators.

11. The filter of claim 9, wherein each of the plurality of series resonators is configured to have a same resonance frequency.

12. The filter of claim 9, wherein the series unit comprises the plurality of series resonators.

13. The filter of claim 9, wherein the shunt unit comprises a trimming inductor connected to each of the first set of shunt resonators.

14. The filter of claim 13, wherein the trimming inductor improves at least one of insertion loss and reflection loss of the filter.

15. The filter of claim 1, wherein the filter has a bandwidth of 100 to 200 MHz.

16. The filter of claim 9, wherein each of the plurality of series resonators and the plurality of shunt resonators comprises a volume acoustic resonator.

17. A filter comprising:
a series unit comprising a plurality of series resonators; and
a shunt unit comprising a plurality of shunt resonators;
wherein the plurality of shunt resonators is disposed between the plurality of series resonators and a ground; and
wherein each of the plurality of series resonators and the plurality of shunt resonators comprises a volume acoustic resonator, and a resonance frequency of a first set of series resonators among the plurality of series resonators is equal to the resonance frequency of the plurality of shunt resonators.

18. The filter of claim 17, wherein the resonance frequency of the first set of series resonators among the plurality of series resonators is different from the resonance frequency of a second set of series resonators of the plurality of series resonators.

19. The filter of claim 17, wherein each of the plurality of shunt resonators has a same resonance frequency.

20. The filter of claim 17, wherein the series unit comprises a trimming inductor connected in parallel to each of the first set of series resonators.

21. The filter of claim 1, wherein the first set of shunt resonators corresponds to one or more than one shunt resonators, and the second set of shunt resonators corresponds to one or more than one shunt resonators.

22. The filter of claim 9, wherein the first set of series resonators corresponds to one or more than one series resonators, the first set of shunt resonators corresponds to one or more than one shunt resonators, and the second set of shunt resonators corresponds to one or more than one shunt resonators.

23. The filter of claim 18, wherein the first set of series resonators corresponds to one or more than one series resonators, and the second set of series resonators corresponds to one or more than one series resonators.
